(19) United States
(12) Patent Application Publication
(10) Pub. No.: US 2005/0247857 A1
(43) Pub. Date: Nov. 10, 2005

(54) Solid-state imaging device and CCD linear sensor

(76) Inventor: Toshimitsu Nagae, Fukuoka (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/113,556

(22) Filed: Apr. 25, 2005

(30) Foreign Application Priority Data
Apr. 26, 2004 (JP) P2004-129628

(51) Int. Cl. H01L 27/00

(52) U.S. Cl. 250/208.1

(57) ABSTRACT

A solid-state imaging device in which a clock pulse transmission line for transmitting a transfer clock pulse is provided substantially in parallel with a charge transfer section in which a plurality of charge transfer elements are arrayed, wherein the clock pulse transmission line is formed from a plurality of transmission lines for transmitting transfer clock pulses, which are the same.

### CROSS REFERENCE TO RELATED APPLICATIONS

The present invention contains subject matter related to Japanese Patent Application JP2004-129628, filed in the Japanese Patent Office on Apr. 26, 2004, the entire contents of which being incorporated herein by reference.

### BACKGROUND OF THE INVENTION

1. Field of the Invention

The present invention relates to a solid-state imaging device having a linearly-shaped charge transfer section, and to a CCD linear sensor.

2. Description of Related Art

Traditionally, in a CCD (Charge Coupled Device) linear sensor and a CCD solid-state imaging device, a plurality of light-sensitive elements are arranged together in one direction, and charges accumulated in these light-sensitive elements are transferred to transfer registers of charge transfer means. Then, by applying a voltage to these transfer registers in response to a transfer clock pulse, the charges are transferred to an output circuit.

The charge transfer means for transferring charges has a charge transfer section that is linearly shaped by arranging a plurality of transfer registers together in substantially parallel with the light-sensitive elements, and also has a clock pulse transmission line provided in substantially parallel with this charge transfer section. A transfer clock pulse generated by a clock pulse generating circuit, such as a timing generator, is inputted from an input section provided at one end of the clock pulse transmission line, for transmission to the charge transfer section.

In such charge transfer means, where the clock pulse transmission line is relatively long such as that of a solid-state imaging device, a CCD linear sensor, or the like that is of a large size, a transfer clock pulse inputted from the input section of the clock pulse transmission line has its waveform attenuated due to resistive component and capacitive component of the clock pulse transmission line itself during transfer to the terminal end of the clock pulse transmission line. As a result, if a transmission length of the clock pulse transmission line from the input section becomes large, there has been a possibility that a normal transfer clock pulse cannot be obtained at that portion.

Thus, another input section for inputting a transfer clock pulse is provided also at a terminal end region where the transmission length of the clock pulse transmission line becomes largest, and the transfer clock pulse is inputted to this input section, whereby the actual transmission length at the terminal end region where the transmission length has been large is shortened, to suppress attenuation of the transfer clock pulse (e.g., see Japanese Patent Application Publication No. Hei 6-268186).

### SUMMARY OF THE INVENTION

However, where a transfer clock pulse is inputted not only from the first input section provided beforehand at the clock pulse transmission line but also from the second input section newly provided at the terminal end region of the clock pulse transmission line, the transfer clock pulses inputted from the different input sections interfere with each other within the clock pulse transmission line, i.e., the clock pulses from both input sections are synthesized, with the signals individually attenuating and delaying, whereby an unintended clock waveform is generated, which has brought about the possibility of deteriorating the transfer characteristics.

Thus, in a solid-state imaging device of the present invention in which a clock pulse transmission line for transmitting a transfer clock pulse therethrough is provided substantially in parallel with a charge transfer section in which a plurality of charge transfer elements are arrayed, the clock pulse transmission line is formed from a plurality of transmission lines for transmitting transfer clock pulses, which are the same, therethrough.

Further, it is also characterized in that adjacent terminals of the plurality of transmission lines are substantially equidistant from transfer clock pulse input sections of the transmission lines, respectively, and further that the terminals of the adjacent transmission lines are connected through a resistive element.

Furthermore, in a CCD linear sensor of the present invention in which a clock pulse transmission line for transmitting a transfer clock pulse therethrough is provided substantially in parallel with a charge transfer section in which a plurality of charge transfer elements are arrayed, the clock pulse transmission line is formed from a plurality of transmission lines for transmitting transfer clock pulses, which are the same, therethrough.

According to an embodiment of the present invention, a clock pulse transmission line is formed from a plurality of transmission lines for transmitting transfer clock pulses, which are the same, therethrough, whereby each of the transmission lines can be made to have such a length as not to cause large attenuations in the transfer clock pulse to be transmitted therethrough, and thus proper transfer clock pulses can be transmitted to the charge transfer section reliably.

According to an embodiment of the present invention, adjacent terminals of the plurality of transmission lines are substantially equidistant from transfer clock pulse input sections of the transmission lines, respectively, whereby transfer clock pulses having attenuated in similar degrees are transmitted to the adjacent terminals of one and the other of the transmission lines, respectively. Therefore, charges transferred by the transfer clock pulse through the one of the transmission lines can be smoothly delivered for transfer by the transfer signal through the other transmission line, and thus occurrence of inconvenience in transfer of charges can be suppressed.

According to an embodiment of the present invention, the adjacent terminals of the transmission lines are connected through a resistive element, whereby a transfer clock pulse at one of the transmission lines which are adjacent to each other through the resistive element can be made to synchronize with a transfer clock pulse at the other transmission line, and thus occurrence of inconvenience in charge transfer due to occurrence of phase differences in the transfer clock pulses between the one and the other of the transmission lines can be suppressed.

According to an embodiment of the present invention, a clock pulse transmission line is formed from a plurality of transmission lines for transmitting transfer clock pulses, which are the same, therethrough. Therefore, similarly to the above, each of the transmission lines can be made to have such a length as not to cause large attenuations in the transfer clock pulse to be transmitted therethrough, and thus proper transfer clock pulses can be transmitted to the charge transfer section reliably.

### BRIEF DESCRIPTION OF THE DRAWINGS

FIG. 1 is a schematic diagram of a CCD linear sensor according to the present invention;

FIG. 2 is a schematic diagram of a CCD linear sensor according to another embodiment;

FIG. 3 is a schematic diagram of a CCD linear sensor according to another embodiment; and

FIG. 4 is a schematic diagram of a CCD linear sensor according to another embodiment.

### DESCRIPTION OF THE EMBODIMENTS

A solid-state imaging device of the present invention, including, most notably, a CCD linear sensor, has a charge transfer section formed by linearly arraying a plurality of charge transfer elements provided for transferring charges, and also a clock pulse transmission line for supplying a required transfer clock pulse to this charge transfer section.

And the clock pulse transmission line to be provided substantially in parallel with the charge transfer section is formed from a plurality of transmission lines which are arranged together in a row, for input of transfer clock pulses to the transmission lines, respectively.

That is, the clock pulse transmission line, which has conventionally been formed from a single transmission line, is divided at predetermined positions to be formed into a plurality of transmission lines. Thus, transmission clock pulses, which are the same, are inputted to the respective transmission lines to perform transfer of charges at the charge transfer section.

In this way, the clock pulse transmission line is formed from divided transmission lines, to input one transfer signal to the respective transmission lines, whereby occurrence of waveform irregularities in the transfer clock pulses can be suppressed at the transmission lines.

Further, in adjacent transmission lines, opposed terminals of the transmission lines are made substantially equidistant from input sections for inputting the transfer clock pulses to the transmission lines, respectively.

Therefore, in the opposed terminals of the adjacent transmission lines, the transfer clock pulses inputted from the input sections of the respective transmission lines are transmitted therethrough, both being attenuated and delayed to similar degrees while satisfying a desired value. Thus, charges transferred by the transfer clock pulse through one of the transmission lines can be delivered smoothly for transfer by the transfer clock pulse through the other transmission line.

Additionally, where the terminals of the adjacent transmission lines are connected through a resistive element having a resistance higher than resistances of the transmission line portions, weak electrical connection can be accomplished, allowing the transfer clock pulse at one of the adjacent transmission lines and the transfer clock pulse at the other transmission line to be synchronized with each other. Therefore, occurrence of inconvenience in charge transfer due to occurrence of phase differences in the transfer clock pulses between the one and the other of the transmission lines can be suppressed.

An embodiment of the present invention will be described below in detail with reference to the drawings. It should be noted that in the following, a solid-state imaging device is described as a CCD linear sensor, but that a similar configuration may also be used in a horizontal register portion in CCD area sensors.

A CCD linear sensor A of the present embodiment has a sensor section 10 formed by arranging light-sensitive elements formed from photodiodes, in a row, a charge transfer section 20 formed from CCD registers arranged together with the sensor section 10, and a first transfer clock pulse transmission line 31 and a second transfer clock pulse transmission line 32 for applying a voltage to drive the charge transfer section 20 in response to transfer clock pulses.

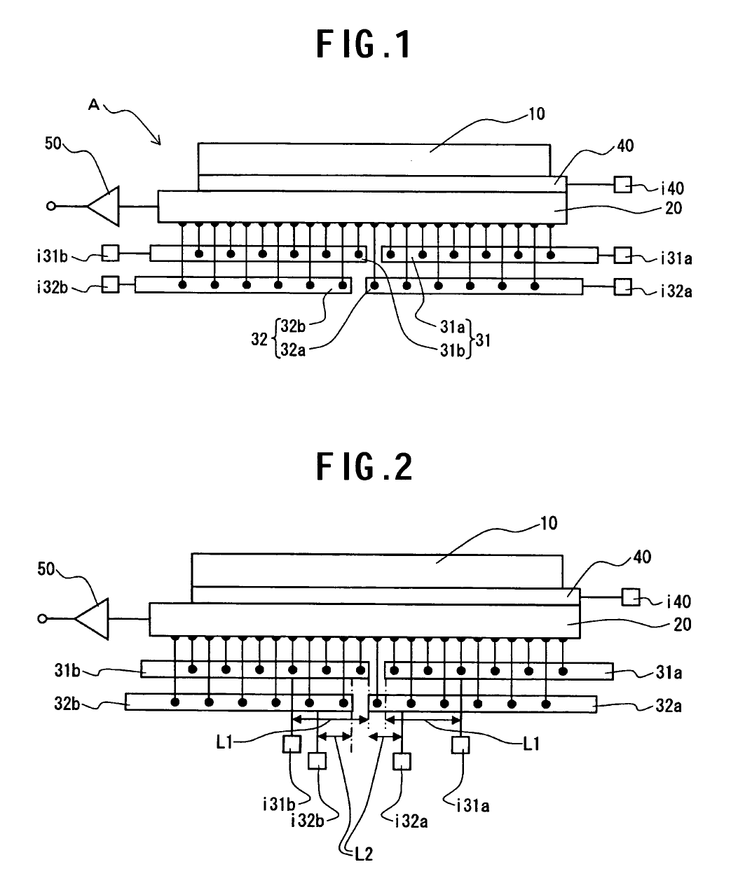

In FIG. 1, reference symbol 40 denotes a read-out gate for reading out charges accumulated in the light-sensitive elements of the sensor section 10 to the respective registers of the charge transfer section 20, and a reference symbol i40 denotes an operating voltage input terminal to which an operating voltage for operating the read-out gate is inputted. In FIG. 1, reference symbol 50 denotes an output circuit for performing a required process on the charges outputted from the charge transfer section 20, for output therefrom.

The first transfer clock pulse transmission line 31 is formed from a first transmission line 31a and a second transmission line 31b separated approximately halfway along the length of the line, unlike a transmission line in a related art, which is formed from a single line. At one end of the first transmission line 31a is a first input section i31a, and at one end of the second transmission line 31b is a second input section i31b. To the first input section i31a and the second input section i31b, predetermined first transfer clock pulses generated by a timing generator circuit or the like, which is not shown, are inputted.

The second transfer clock pulse transmission line 32 is formed from a third transmission line 32a and a fourth transmission line 32b separated approximately halfway along the length of the line, unlike the conventional transmission line which is formed from a single line. At one end of the third transmission line 32a is a third input section i32a, and at one end of the fourth transmission line 32b is a fourth input section i32b. To the third input section i32a and the fourth input section i32b, predetermined second transfer clock pulses generated by a timing generator circuit or the like, which is not shown, are inputted.

In this way, the first transfer clock pulse transmission line 31 is formed by division into the first transmission line 31a and the second transmission line 31b, and the first transfer clock pulses are inputted to the respective lines, respectively, whereby occurrence of irregularities in the waveforms of the inputted first transfer clock pulses can be suppressed through the first transmission line 31a and the second transmission line 31b, and charge transfer at the charge transfer section 20 can thus be performed stably.

Similarly, the second transfer clock pulse transmission line 32 is formed by division into the third transmission line 32a and the fourth transmission line 32b, and the second transfer clock pulses are inputted to the respective lines, respectively, whereby occurrence of irregularities in the waveforms of the inputted second transfer clock pulses can be suppressed in the third transmission line 32a and the fourth transmission line 32b, and charge transfer at the charge transfer section 20 can thus be performed stably.

Particularly, the lengths of the first to fourth transmission lines 31a, 31b, 32a, 32b are fixed to such lengths which does not cause large attenuations in the transfer clock pulses to be transmitted through the first to fourth transmission lines 31a, 31b, 32a, 32b, respectively, whereby transfer clock pulses can surely be transmitted to the charge transfer section 20 reliably.

Here, lengths of the first to fourth transmission lines 31a, 31b, 32a, 32b are considered. Between from the first to fourth input sections i31a, i31b, i32a, i32b to the first to fourth transmission lines 31a, 31b, 32a, 32b, regions where resistive components and capacitive components are negligible compared with those in the first to fourth transmission lines 31a, 31b, 32a, 32b are not to be included in the first to fourth transmission lines 31a, 31b, 32a, 32b, and the length of each of these regions is deemed to be “zero”.

As described above, where the first transfer clock pulse transmission line 31 is formed from the first transmission line 31a and the second transmission line 31b, a distance from the first input section i31a to a terminal of the first transmission line 31a and a distance from the second input section i31b to a terminal of the second transmission line 31b are made substantially equal.

In this way, the terminal of the first transmission line 31a and the terminal of the second transmission line 31b, which are adjacent to each other, are made substantially equidistant from the input sections i31a, i31b from which the first transfer clock pulses are inputted in the transmission lines 31a, 31b, respectively, whereby the first transfer clock pulses which have been attenuated in similar degrees are transmitted to the terminal of the first transmission line 31a and the terminal of the second transmission line 31b. As a result, charges at the charge transfer section 20 which have been transferred by the first transfer clock pulse through the first transmission line 31a can be delivered smoothly for transfer by the first transfer clock pulse through the second transmission line 31b.

Similarly, where the second transfer clock pulse transmission line 32 is formed from the third transmission line 32a and the fourth transmission line 32b, a distance from the third input section i32a to a terminal of the third transmission line 32a and a distance from the fourth input section i32b to a terminal of the fourth transmission line 32a are made substantially equal.

As another embodiment, instead of providing the first input section i31a and the second input section i31b or the third input section i32a and the fourth input section i32b at both terminals of the first transfer clock pulse transmission line 31 or the second transfer clock pulse transmission line 32, respectively, the first input section i31a and the second input section i31b may be provided in the vicinity of the terminal of the first transmission line 31a and the terminal of the second transmission line 31b, which are adjacent to each other, as shown in FIG. 2. Similarly, the third input section i32a and the fourth input section i32b may be provided in the vicinity of the terminal of the third transmission line 32a and the terminal of the fourth transmission line 32b, which are adjacent to each other.

In the case of FIG. 2, a distance from the first input section i31a to the terminal of the first transmission line 31a, and a distance from the second input section i31b to the terminal of the second transmission line 31b are set to L1, respectively, and a distance from the third input section i32a to the terminal of the third transmission line 32a, and a distance from the fourth input section i32b to the terminal of the fourth transmission line 32b are set to L2, respectively.

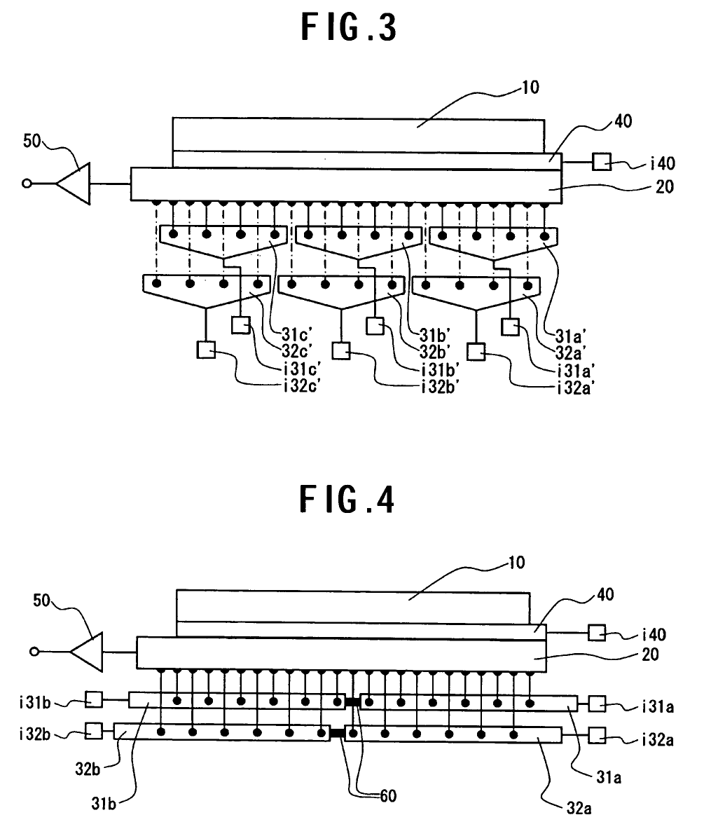

As still another embodiment, instead of dividing each of the first transfer clock pulse transmission line 31 and the second transfer clock pulse transmission line 32 into two parts, each of these lines may also be divided into three or more parts, as shown in FIG. 3.

That is, the first transfer clock pulse transmission line is formed from a first transmission line 31a′, a second transmission line 31b′, and a third transmission line 31c′. Further, the second transfer clock pulse transmission line is formed from a fourth transmission line 32a′, a fifth transmission line 32b′, and a sixth transmission line 32c′. To the first to third transmission lines 31a′ to 31c′, first transfer clock pulses are inputted from first to third input sections i31a′ to i31c′, respectively, and to the fourth to sixth transmission lines 32a′ to 32c′, second transfer clock pulses are inputted from fourth to sixth input sections i32a′ to i32c′, respectively.

Here, the first to sixth transmission lines 31a′ to 32c′ are designed such that each of the first to sixth input sections i31a′ to i32c′ is provided at an approximately halfway portion thereof to input a corresponding one of the first transfer clock pulses or the second transfer clock pulses thereto.

Further, in the first to sixth transmission lines 31a′ to 32c′, the widths of their lines are tapered toward their terminals from the vicinity of the first to sixth input sections i31a′ to i32c′, respectively, thereby to minimize the influence of resistive components and capacitive components in the lines which increase as they move away from the first to sixth input sections i31a′ to i32c′, respectively.

As described above, the first transfer clock pulse transmission line 31 and the second transfer clock pulse transmission line 32 are divided into a required number of parts. In addition thereto, as shown in FIG. 4, between a terminal of the first transmission line 31a and a terminal of the second transmission line 31b, and between a terminal of the third transmission line 32a and a terminal of the fourth transmission line 32b, which lines have been obtained by the division, may be connected through resistive elements 60, resistances of which are larger than resistances of the first to fourth transmission lines 31a, 31b, 32a, 32b, respectively.

In this way, the resistive elements 60 are used to connect between the terminal of the first transmission line 31a and the terminal of the second transmission line 31b, and between the terminal of the third transmission line 32a and the terminal of the fourth transmission line 32b, which lines have been obtained by division, respectively, whereby the first transfer clock pulses through the first transmission line 31a and the first transfer clock pulse through the second transmission line 31b which are adjacent to each other can be made to synchronize with each other, and the second transfer clock pulses through the third transmission line 32a and the second transfer clock pulse through the fourth transmission line 32b which are adjacent to each other can also be made to synchronize with each other.

Therefore, occurrence of phase differences in the first transfer clock pulses between the first transmission line 31a and the second transmission line 31b, and occurrence of phase differences in the second transfer clock pulses between the third transmission line 32a and the fourth transmission line 32b can be suppressed, and thus occurrence of inconvenience in charge transfer at the charge transfer section 20 can be suppressed.

It should be understood by those skilled in the art that various modifications, combinations, sub-combinations and alterations may occur depending on design requirements and other factors insofar as they are within the scope of the appended claims or the equivalents thereof.

1. A solid-state imaging device in which a clock pulse transmission line for transmitting a transfer clock pulse is provided substantially in parallel with a charge transfer section in which a plurality of charge transfer elements are arrayed,
wherein the clock pulse transmission line is formed from a plurality of transmission lines for transmitting transfer clock pulses, which are the same.

2. The solid-state imaging device according to claim 1,
wherein adjacent ends of the plurality of transmission lines are substantially equidistant from transfer clock pulse input sections of the transmission lines, respectively,

3. The solid-state imaging device according to claim 1 or claim 2,
wherein between the ends of the adjacent transmission lines are connected through a resistive element.

4. A CCD linear sensor in which a clock pulse transmission line for transmitting a transfer clock pulse is provided substantially in parallel with a charge transfer section in which a plurality of charge transfer elements are arrayed,
wherein the clock pulse transmission line is formed from a plurality of transmission lines for transmitting transfer clock pulses, which are the same.
